(19) United States
(12) Patent Application Publication
(10) Pub. No.: US 2020/0041893 A1
(43) Pub. Date: Feb. 6, 2020

(54) METHOD OF PRODUCING BOARD INCLUDING RESIST FILM AND PROCESS MANAGEMENT SYSTEM FOR PRODUCING BOARD INCLUDING RESIST FILM

(71) Applicant: SHARP KABUSHIKI KAISHA, Sakai City (JP)

(72) Inventors: MASAHIRO YAMADA, Sakai City (JP); TETSUYA KIDA, Sakai City (JP); HIROAKI OKAJIMA, Sakai City (JP)

(21) Appl. No.: 16/523,545

(22) Filed: Jul. 26, 2019

Related U.S. Application Data
(60) Provisional application No. 62/714,591, filed on Aug. 3, 2018.

(51) Int. Cl. G03F 1/38; G03F 7/32; G03F 1/60

(52) U.S. Cl. CPC G03F 1/38; G03F 1/60; G03F 7/325

(57) ABSTRACT

A method of producing a substrate including a resist film includes a coating step of coating a resist film on a substrate, an exposing step of exposing selectively the resist film formed in the coating step, and a developing step of developing the resist film that is selectively exposed in the exposing step and adjusting process time for development based on transition time for shifting to the developing step after the coating step.

### CROSS REFERENCE TO RELATED APPLICATION

This application claims priority from U.S. Provisional Patent Application No. 62/714,591 filed on Aug. 3, 2018. The entire contents of the priority application are incorporated herein by reference.

### TECHNICAL FIELD

The technology described herein relates to a method of producing a board including a resist film and a process management system for producing the board including the resist film.

### BACKGROUND ART

A coating and developing apparatus of performing coating of resist liquid and developing after the exposure for a substrate such as a semiconductor wafer a LCD substrate (a glass substrate for a liquid crystal display) described in Japanese Unexamined Patent Application Publication No. 2009-43927 has been known as an example of such a device. The coating and developing apparatus performs calculation as follows. With regard to a group of substrates preceding a substrate of which residence time is under calculation, a time t1 and a time t2 are calculated on the basis of a residual time t3 in the exposing device calculated from carry-in and carry-out times of the substrate to and from the exposing device, t1 is a time interval from a time point in which a substrate under the consideration has become ready from being transferred out from a wait module to a time point in which a heating module used for the substrate has been ready for processing the substrate. t2 is a time interval from a time on in which the substrate under calculation has been transferred out from the wait module to a time point of reaching the heating module used for the substrate. A waiting time of the substrate in the wait module is calculated according to t1-t2.

According to the coating and developing apparatus, the substrate prior to the exposure is transferred out from the wait module effectively at a timing corresponding to the time point in which the heating module for heating the substrate after the exposure is ready for the heating, and the substrate is less likely to wait for too much time in the wait module.

A transition time until the substrate coated with the resist liquid is ready for the development after the coating of the resist liquid over the substrate may be varied due to various reasons in a producing process. Even in such a case, the process time for development of the substrate is generally constant in a conventional developing device. Therefore, if the transition time is varied, variation may be caused in an obtained pattern of the developed resist film.

### SUMMARY

The technology described herein was made in view of the above circumstances. An object is to form a pattern on a resist film appropriately.

A method of producing a substrate including a resist film according to the technology described herein includes a coating step of coating a resist film on a substrate, an exposing step of exposing selectively resist film formed in the coating step, and a developing step of developing the resist film that is selectively exposed in the exposing step and adjusting process time for development based on transition time for shifting to the developing step after the coating step.

A process management system for producing a substrate including a resist film according to the technology described herein includes a coating device configured to coating a resist film on a substrate, an exposing device configured to selectively expose the resist film, a developing device configured to develop the resist film, a storing device configured to store at least coating finish time that is time when the coating device finishes coating of the resist film, an extraction process device configured to read out the coating finish time stored in the storing device to extract transition time for shifting to development by the developing device after the coating of the resist film by the coating device, and configured to extract process time for development by the developing device based on the extracted transition time, a development control device configured to control development by the developing device based on the process time extracted by the extraction process device, and information transmit lines connecting at least the coating device, the extraction process device, and the development control device to the storing device so as to transmit information therebetween.

According to the technology described herein, a pattern is formed on the resist film appropriately.

### BRIEF DESCRIPTION OF THE DRAWINGS

FIG. 1 is a cross-sectional view generally illustrating a liquid crystal panel according to one embodiment.

FIG. 2 is a plan view illustrating pixel arrangement on a CF substrate of a liquid crystal panel.

FIG. 3 is a cross-sectional view illustrating a mother glass substrate that is coated with a light blocking resist film in a coating step included in a light blocking section forming process.

FIG. 4 is a cross-sectional view illustrating the light blocking resist film that is exposed through a photomask in an exposing step included in the light blocking section forming process.

FIG. 5 is a cross-sectional view illustrating the light blocking resist film that is developed in a developing step included in the light blocking section forming process.

FIG. 6 is a cross-sectional view illustrating a mother glass substrate that is coated with a color resist film in a coating step included in a color filter forming process.

FIG. 7 is a cross-sectional view illustrating the color resist film that is exposed through a photomask in an exposing step included in the color filter forming process.

FIG. 8 is a cross-sectional view illustrating the color resist film that is developed in a developing step included in the color filter forming process.

FIG. 9 is a cross-sectional view schematically illustrating a developing device.

FIG. 10 is a block diagram of a process management system for producing a CF substrate.

FIG. 11 is a graph representing relations between transition time necessary for shifting to a developing step after the coating step and process time necessary for development.

FIG. 12 is a graph representing relations between transition time obtained when the process time for the development is fixed to certain reference process time and a line width of a pattern on the resist film obtained after the developing step.

FIG. 13 is a graph representing relations between transition time obtained when the process time necessary for development is varied according to actual transition time and a line width of a pattern of the resist film obtained after the developing step.

FIG. 14 is a data table representing relations between transition time necessary for shifting to the development after the coating with the resist film and transfer speed of the mother glass substrate.

### DETAILED DESCRIPTION

### Embodiment

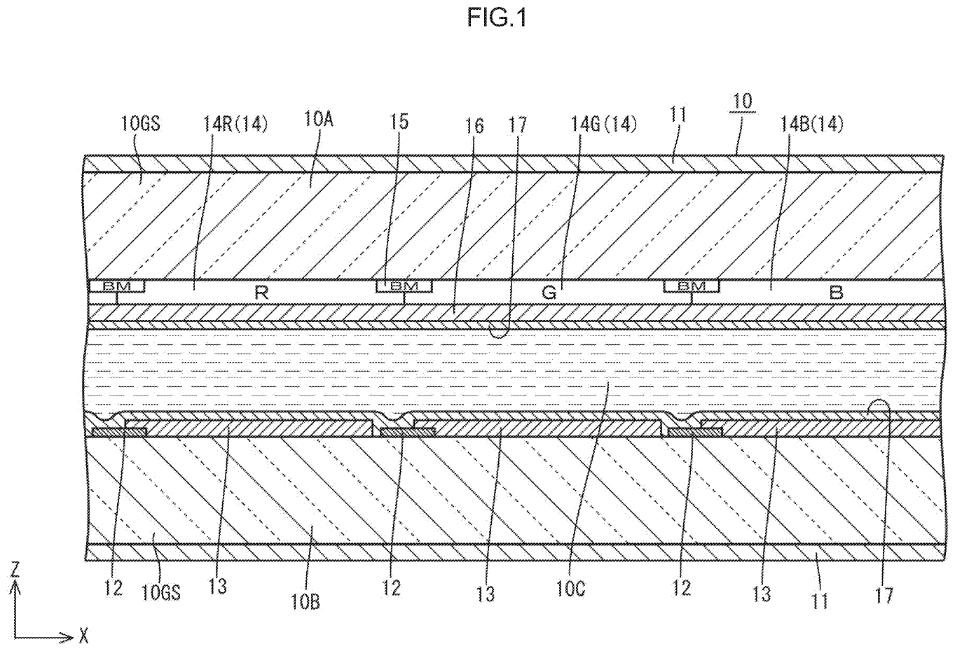

One embodiment will be described with reference to FIGS. 1 to 4. In the section, a method of producing a CF substrate (a substrate including a resist film) 10A included in a liquid crystal panel 10 and a process management device MS for producing the CF substrate 10A will be described as examples. X-axis, Y-axis and Z-axis may be present in the drawings and each of the axial directions represents a direction represented in each drawing. An upper side and a lower side in FIG. 1 correspond to a front side and a back side, respectively.

FIG. 1 is a cross-sectional view of the liquid crystal panel 10. As illustrated in FIG. 1, the liquid crystal panel 10 includes a pair of glass substrates 10A, 10B and a liquid crystal layer 10C sealed between the substrates 10A, 10B. The liquid crystal layer 102 includes liquid crystal material that is a substance whose optical characteristics are changed according to application of an electric field. One on the front side is a CF substrate 10A and the other one on the rear side is an array substrate 10B. The CF substrate 10A may be referred to as a counter substrate and the array substrate 10B may be referred to as an active matrix substrate or a thin film transistor substrate. Each of the CF substrate 10A and the array substrate 10B includes a glass substrate 10GS having transparency and highly transmissivity and predetermined films on inner surfaces thereof. The predetermined films, which are components, are stacked on each other sequentially with the known photolithography method. Front and rear side polarizing plates 11 are bonded on outer surfaces of the respective boards 10A and 10B.

As illustrated in FIG. 1, on an inner surface side of the array substrate 10B that is on a plate surface thereof opposite the liquid crystal layer 10C, TFTs (thin film transistors) 12, which are switching components, and pixel electrodes 13 are disposed in a matrix. Gate lines and source lines that are portions of metal film are routed in a matrix to surround the TFTs 12 and the pixel electrodes 13. The gate lines and the source lines are connected to the TFTs 12. The pixel electrode 13 is made of transparent electrode material such as indium tin oxide (ITO) for example, and is configured to be charged at a certain potential by the TFT 12 that is driven by signals supplied through the gate line and the source line.

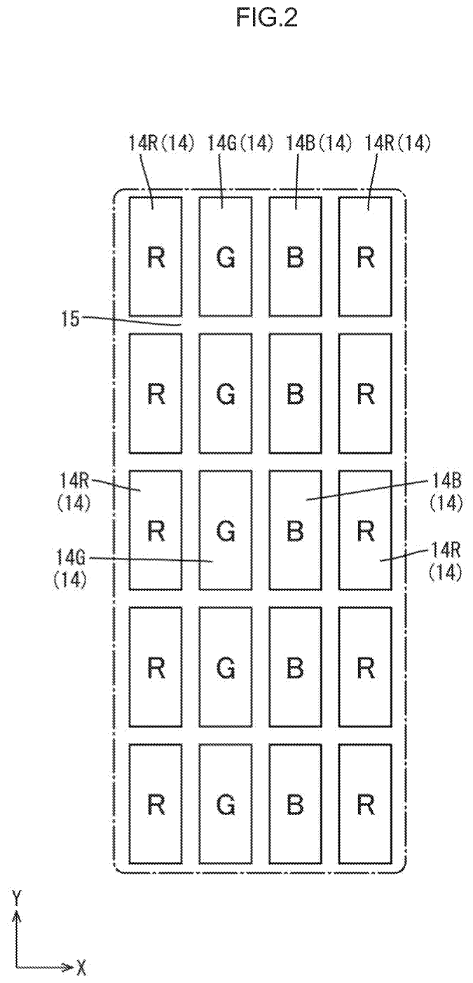

A configuration of the CF substrate 10A will be described with reference to FIGS. 1 and 2. FIG. 2 is a plan view illustrating pixel arrangement of the CF substrate 10A. As illustrated in FIGS. 1 and 2, on an inner plate surface of the substrate 10A, color filters 14 of three colors exhibiting red (R), green (C), and blue (B) and a light blocking section 15 blocking light are disposed. The color filters 14 are arranged in a matrix to be opposite the respective pixel electrodes 13 on the array substrate 10B side. Light having specific wavelength range for each color selectively transmits through a corresponding color filter 14. Namely, red light having a red wavelength range selectively transmits through the red color filter 14R. Green light having a green wavelength range selectively transmits through the green color filter 14G. Blue light having a blue wavelength range selectively transmits through the blue color filter 14B. The color filters 14R, 14B, 14B of the three colors and the respective opposing pixel electrodes 13 configure pixels of three colors. The light blocking section 15 is disposed to define each of the adjacent color filters 14 (the pixels) and blocks light from traveling between the adjacent color filters 14. The light blocking section 15 overlaps the gate lines and the source lines on the array substrate 10B side in a plan view.

As illustrated in FIG. 1, a counter electrode 16 is included in a layer upper than the color filters 14 while overlapping the color filters 14 on an inner side. The counter electrode 16 is formed in a solid manner over a substantially entire area of an inner surface of the CF substrate 10A. The counter electrode is made of the transparent electrode material same as that of pixel electrode 13 and is always maintained at a constant reference potential. Therefore, if each of the pixel electrodes 13 connected to the corresponding TFTs 12 is charged according to the driving of each TFT 12, potential difference is created between the counter electrode 16 and each pixel electrode 13. According to the potential difference created between the counter electrode 16 and each pixel electrode 13, alignment of the liquid crystal molecules included in the liquid crystal layer 10C is changed and accordingly, polarization of the transmit light is changed. Thus, the amount of transmission light through the liquid crystal panel 10 is controlled independently for every pixel and predetermined color images are displayed. Alignment films 17 through which the liquid crystal molecules are aligned are disposed on most inner surfaces of the substrates 10A, 10B to face the liquid crystal layer 10C.

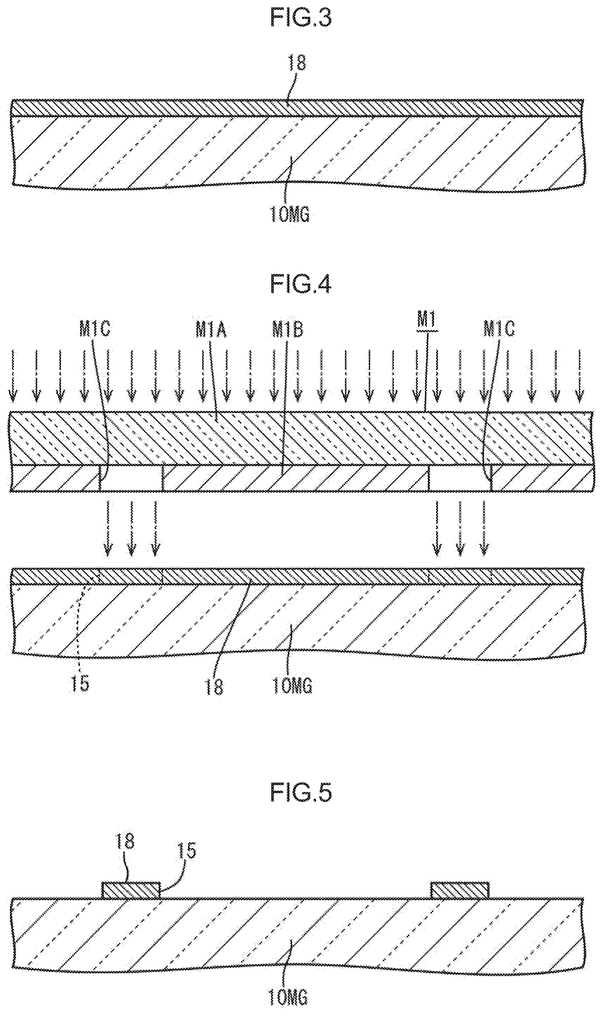

Each of the substrates 10A, 10B having the above structure is produced by forming repeatedly various kinds of films for forming various components on an inner plate surface of the glass substrate 10GS with the known photolithography method. In the present embodiment, various kinds of processes necessary for the photolithography method (refer FIG. 3 or other drawings) are performed for the mother glass substrate 10MG including glass substrates 10GS that are arranged within a plate surface area of the mother glass substrate 10MG. The glass substrate 10GS corresponds to “a unit substrate” that configures each liquid crystal panel 10 and the mother glass substrate 10MG corresponds to “a substrate” including multiple unit substrates.

Next, a method of producing the CF substrate 10A will be described in detail. The CF substrate 10A is produced through a light blocking section forming process of forming the light blocking section 15 on the mother glass substrate 10MG, a color filter forming process of forming sequentially the color filters 14R, 14G, 14B of three colors, a counter electrode forming process of forming the counter electrode 16, and an alignment film forming process of forming the alignment film 17. Among the above processes, in the light blocking section forming process and the color filter forming process, negative-type photosensitive material is used as the material for the light blocking section 15 and the color filter 14. Specifically, each of the light blocking section forming process and the color filter forming process includes a coating step of coating a resist film (a photoresist film) 18, 19 made of the negative-type photosensitive material over the mother glass substrate 10MG, an exposing step of selectively exposing the resist film 18, 19, and a developing step of developing the resist film 18, 19.

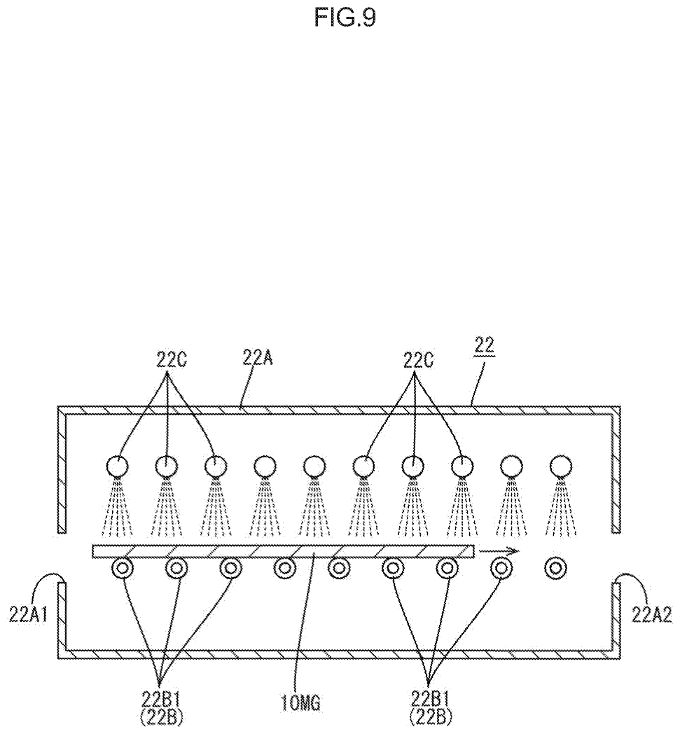

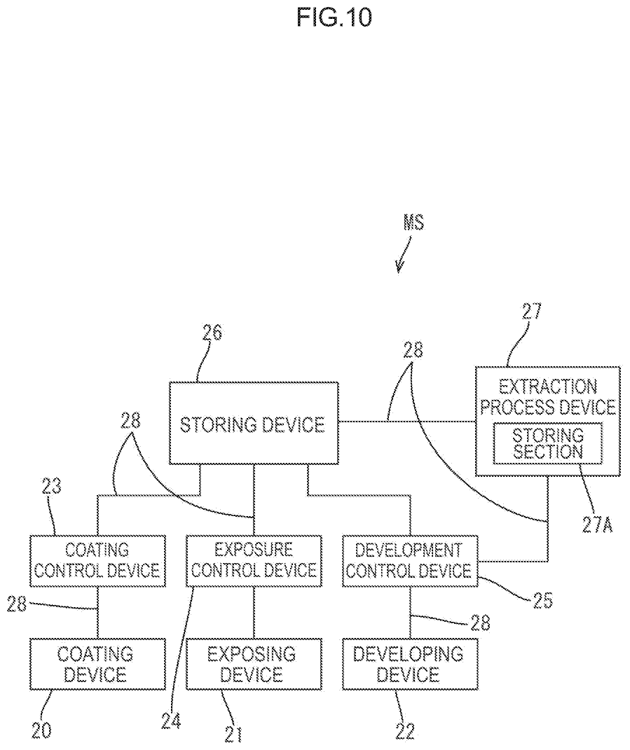

The light blocking section forming process will be described with reference to FIGS. 3 to 5. FIGS. 3 to 5 are cross-sectional views illustrating a sequence of transferring a pattern on a light blocking resist film (a resist film) 18 in the light blocking section forming process. As illustrated in FIG. 3, in the coating step included in the light blocking section forming process, the light blocking resist film 18 made of negative-type photosensitive light blocking material is disposed with coating over the mother glass substrate 10MG by a coating device 20 (see FIG. 10) such as an ink jetting device. The light blocking resist film 18 is disposed in a solid manner with a substantially constant film thickness on the plate surface of the mother glass substrate 10MG. As illustrated in FIG. 4, in the exposing step included in the light blocking section forming process, the light blocking resist film 18 disposed on the mother glass substrate 10MG is selectively exposed by an exposing device 21 (see FIG. 10). The exposing device 21 includes a photomask M1 with which an exposure area in the light blocking resist film 18 is controlled. The photomask M1 includes a transparent glass substrate M1A and a light blocking film M1B that is formed on a plate surface of the glass substrate M1A and blocks exposure light from source. The light blocking film M1B includes holes M1C through which light passes. The blocking resist film 18 has a non-exposed section that overlaps the light blocking film M1B of the photomask M1 and an exposed section that overlaps each of the holes M1C. As illustrated in FIG. 5, the developing step included in the light blocking section forming process, the light blocking resist film 18 that is selectively exposed is developed by the developing device 22 (see FIG. 9 and FIG. 10). In the present embodiment, the negative-type photosensitive light blocking material is used for the light blocking resist film 18. Therefore, through the developing step, the non-exposed section of the light blocking resist film 18 is removed from the mother glass substrate 10MG and the exposed section remains on the mother glass substrate 10MG. The residual section of the light blocking resist film 18 will be the light blocking section 15 having a predetermined pattern.

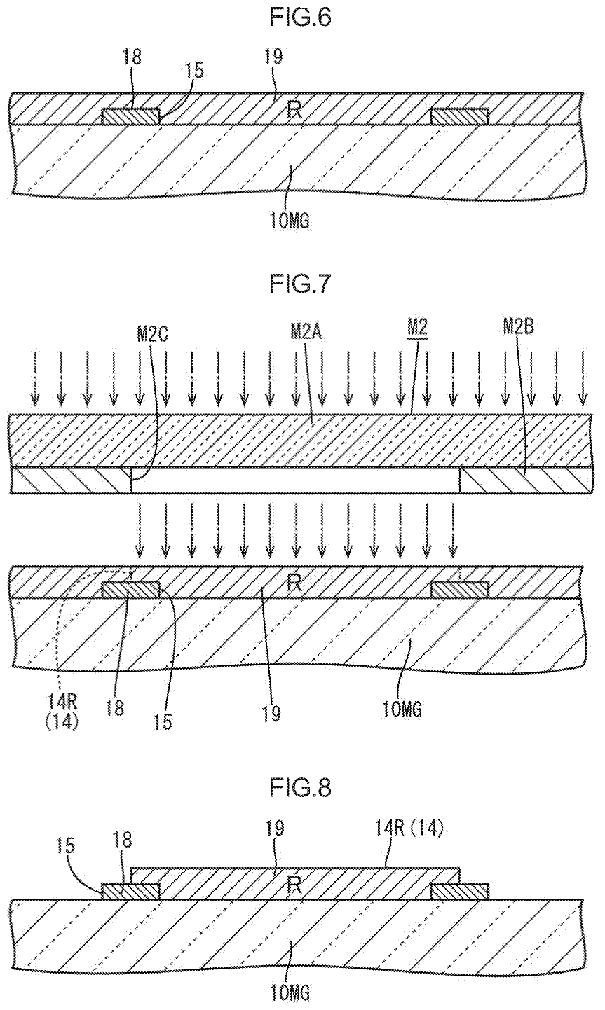

The color filter forming process will be described with reference to FIGS. 6 to 8. FIGS. 6 to 8 are cross-sectional views illustrating a sequence of transferring a pattern on the color resist film (a resist film) 19 in the color filter forming process. In FIGS. 6 to 8, the red color filter 14R is illustrated as an example of the color filter 14 but the green color filter 14G and the blue color filter 14B are formed similarly. As illustrated in FIG. 6, in the coating step included in the color filter forming process, the color resist film 19 made of negative-type photosensitive coloring material is disposed on the mother glass substrate 10MG by the coating device 20 such as an ink jetting device similar to that used in the light blocking section forming process. The photosensitive coloring material of the color resist film 19 contains a pigment that exhibits a color different for each of true color filters 14R, 14G, 14B. The color resist film 19 is disposed in a solid manner with substantially constant film thickness on the plate surface of the mother glass substrate 10MG. As illustrated in FIG. 7, in the exposing step included in the color filter forming process, the color resist film 19 disposed on the mother glass substrate 10MG is selectively exposed by the exposing device 21 similarly to the light blocking section forming process. The exposing device 21 includes a photomask M2 with which an exposure area in the color resist film 19 is controlled. The photomask M2 includes a transparent glass substrate M2A and a light blocking film M2B that is formed on a plate surface of the glass substrate M2A and blocks exposure light from a source. The light blocking film M2B includes holes M2C through which light passes. The color resist film 19 has a non-exposed section that overlaps the light blocking film M2B of the photomask M2 and an exposed section that overlaps each of the holes M2C. As illustrated in FIG. 8, in the developing step included in the color filter forming process, the color resist film 19 that is selectively exposed is developed by the developing device 22 similarly to the light blocking section forming process. In the present embodiment, the negative-type photosensitive coloring material is used for the color resist film 19. Therefore, through the developing step, the non-exposed section of the color resist film 19 is removed from the mother glass substrate 10MG and the exposed section remains on the mother glass substrate 10MG. The residual section of the color resist film 19 will be the color filter 14 having a predetermined pattern. In the present embodiment, symbols related to the coating device 20, the exposing device 21, and the developing device 22 are commonly used in the light blocking section forming process and the color filter forming process for simple description.

Next, the developing device 22 will be described in detail with reference to FIG. 9. FIG. 9 is schematic cross-sectional view of the developing device 22. As illustrated in FIG. 9, the developing device 22 at least includes a development process tank 22A where the development is performed, a substrate transfer section 22B that transfers the mother glass substrate 10MG within the development process tank 22A, and developer supply section 22C that supplies developer onto the mother glass substrate 10MG that is transferred by the substrate transfer section 22B. The development process tank 22A includes an inlet hole 22A1 and an exit hole 22A2 at front and back walls thereof with respect to a transfer direction of the mother glass substrate 10MG (a right-left direction in FIG. 9), respectively. The mother glass substrate 10MG is introduced through the inlet hole 22A1 and discharged through the exit hole 22A2. The substrate transfer section 22B includes transfer rollers 22B1 with which the mother glass substrate 10MG is transferred while the surface thereof having the resist film 18, 19 facing upward in the vertical direction and being parallel to a horizontal direction. The transfer rollers 22B1 are arranged at intervals in the transfer direction of the mother glass substrate 10MG and rotatable. Each of the transfer rollers 22B1 is rotated at a rotation number per a unit time by rotation power supplied by a power source (such as a motor). The developer supply sections 22C are arranged vertically above the substrate transfer section 22B while having the mother glass substrate 10MG therebetween. The developer supply sections 22C are arranged at intervals in the front and back direction with respect to the transfer direction of the mother glass substrate 10MG. Each of the developer supply sections 22C can eject developer onto the surface of the mother glass substrate 10MG where the resist film 18, 19 is formed. In the developing device 22, the development is performed with the developer elected by the developer supply sections 22C while the mother glass substrate 10MG being transferred by the substrate transfer section 22B at a predetermined transfer speed. Therefore, the process time taken for the development depends on the transfer speed of the mother glass substrate 10MG by the substrate transfer section 22B (a rotation number of each transfer roller 22B1 per unit time). The process time tends to be longer as the transfer speed becomes lower, and the process time tends to be shorter as the transfer speed becomes higher.

Next, a process management system MS used in the light blocking section forming process and the color filter forming process included in the method of producing the CF substrate 10A will be described with reference to FIGS. 10 to 14. As illustrated in FIG. 10, the process management system MS at least includes the coating device 20, a coating control device 23, the exposing device 21, an exposure control device 24, the developing device 22, a development control device 25, a storing device 26, which will be described in detail, an extraction process device 27, which will be described in detail, and information transmit lines 28 that connect the devices 20 to 27 to transmit information therebetween. The coating device 20, the exposing device 21, and the developing device 22 are as described before. The coating control device 23 is connected to the coating device 20 via the information transmit line 28 and configured to control the coating of resist film 18, 19 on the mother glass substrate 10MG performed by the coating device 20 (such as a film thickness of the resist film 18, 19). The exposure control device 24 is connected to the exposing device 21 via the information transmit line 28 and configured to control exposure for the resist film 18, 19 performed by the exposing device 21 (such as an exposure area and a non-exposure area of the resist film 18, 19). The development control device 25 is connected to the developing device 22 via the information transmit line 28 and configured to control development for the resist film 18, 19 performed by the developing device. More specifically, the development control device 25 can control the transfer speed of the mother glass substrate 10MG that is transferred by the substrate transfer section 22B included in the developing device 22 (the number of rotation of each transfer roller 22B1 per unit time) and the ejection amount of the developer ejected by the developer supply section 22C.

As illustrated in FIG. 10, the storing device 26 is connected to the coating control device 23, the exposure control device 24, and the development control device 25 via the information transmit lines 28 and can store time when each of the processes performed by the coating device 20, the exposing device 21, and the developing device 22 is finished (including coating finish time). Other than the above, the storing device 26 stores lot numbers of the mother glass substrates 10MG for which various kinds of processes are to be performed, step numbers of the various kinds of processes, recipe numbers of the various kinds of processes, and so on. The lot number is associated with the step number and the recipe number and also associated with information such as a model of the liquid crystal panel 10 to be produced. The extraction process device 27 is connected to the development control device 25 and the storing device 26 via the information transmit lines 28. The extraction process device 27 is a personal computer including a CPU and a memory (a storing section 27A), for example. The extraction process device 27 is configured at least to read the coating finish time at which the coating of the resist film 18, 19 by the coating device 20 is finished out of the information stored in the storing device 26 through the information transmit line 28. Accordingly, the extraction process device 27 performs a process of extracting transition time necessary for shifting to the development by the developing device 22 after the coating of the resist film 18, 19 by the coating device 20. Furthermore, the extraction process device 27 performs a process of extracting the process time necessary for development by the developing device 22 based on the extracted transition time. The development starting time that is a time when the development by the developing device 22 is supposed to be performed may be stored in the storing device 26. In such a case, the extraction process device 27 reads the coating finish time and the development starting time that are stored in the storing device 26 through the information transmit line 28 and extracts the transition time. Other than the above, the time when the extraction process device 27 extracts the transition time may be referred to as the development starting time. In such a case, the extraction process device 27 reads the coating finish time that is stored in the storing device 26 through the information transmit line 28 and also extracts the transition time with referring the time at this point as the development starting time.

As illustrated in FIG. 10, the development control device 25 controls development by the developing device 22 based on the process time that is extracted by the extraction process device 27. Namely, in the developing step included in the CF substrate producing process, the process time necessary for development is controlled based on the transition time necessary for shifting to the developing step after the coating step. Accordingly, even if the transition time necessary for shifting to the development by the developing device 22 after the coating of the resist film 18, by the coating device 20 is varied due to the various reasons in the producing process, the developing device 22 is controlled by the development control device 25 such that the development is performed for the process time extracted by the extraction process device 27 based on the transition time. For example, if the transition time is long, the long process time is extracted by the extraction process device 27 and the developing device 22 is controlled by the development control device 25 to perform the development for the long process time. On the contrary, if the transition time is short, the short time is extracted by the extraction process device 27 and the developing device 22 is controlled by the development control device 25 to perform the development for the short process time. Accordingly, the development can be performed appropriately even if the above-described transition time is varied. Therefore, the resist film 18, 19 is appropriately processed with patterning. Furthermore, the development control device 25 is connected to the extraction process device 27 via the information transmit line 28 so as to transmit information therebetween. Therefore, the development control device 25 can read the process time that is extracted by the extraction process device 27 directly through the information transmit line 28.

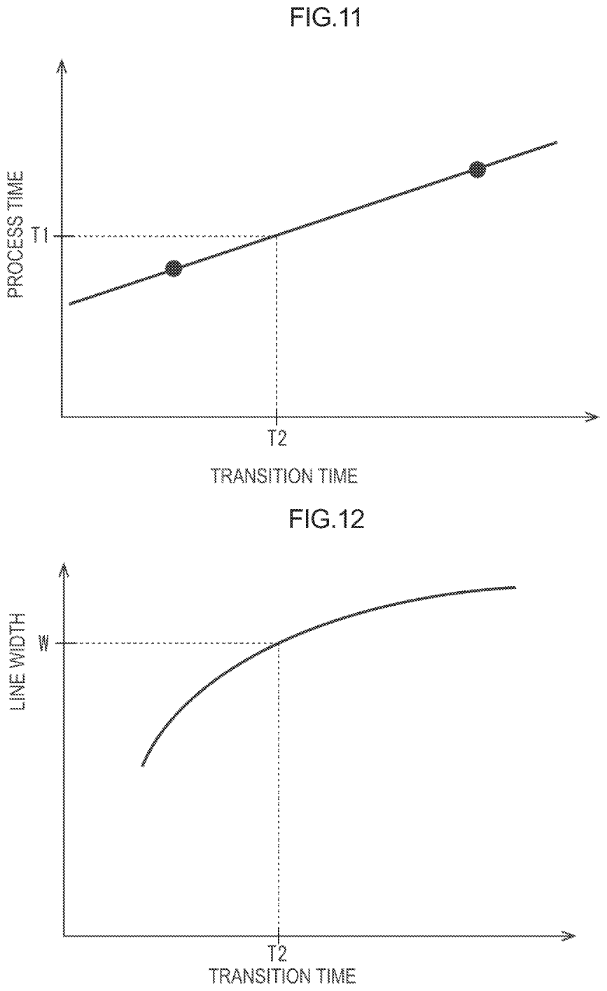

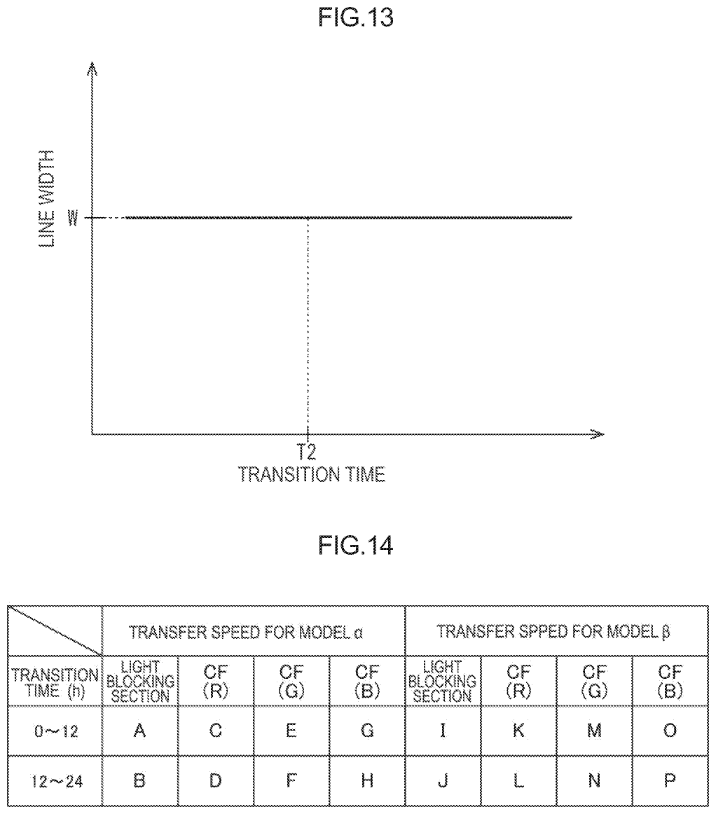

Problems, operations, and advantageous effects of the present embodiment, will be described in detail with reference to the graphs illustrated in FIGS. 11 to 13. FIG. 1 is a graph representing relations between the transition time (a lateral axis) taken for shifting to the developing step after the finish of the coating step and the process time (a vertical axis) necessary for the development. It can be said from FIG. 11 that the process time necessary for development tends to be longer as the transition time is longer and the process time necessary for the development tends to be shorter as the transition time is shorter. If the process time is fixed to certain standard process time T1, standard transition time T2 that is obtained from an intersection of the standard process time and the graph in FIG. 11. Next, FIG. 12 is a graph representing relations between the transition time (a lateral axis) obtained when the process time for the development is fixed to the certain process time T1 and a line width (a vertical axis) of the pattern of the resist film 18, 19 obtained after the developing step. The line width of the pattern of the resist film 18, 19 when the transition time is the standard transition time T2 is a standard line width W. It is found from FIG. 12 that the line width of the pattern of the resist film 18, 19 is greater than the standard line width W if the developing is performed for the standard process time T1 while the actual transition time being longer than the standard transition time T2. This may be caused since the standard process time T1 is shorter than the process time that is actually necessary for the development and the resist film 18, 19 is not sufficiently developed. It is found from FIG. 12 that the line width of the pattern of the resist film 18, 19 is smaller than the standard line width W if the developing is performed for the standard process time T1 while the actual transition time being shorter than the standard transition time T2. This may be caused since the standard process time T1 is longer than the process time that is actually necessary for the development and the resist film 18, 19 is developed too much. Next, FIG. 13 is a graph representing relations between the transition time (a lateral axis) obtained when the process time for the development is varied according to the actual transition time and a line width (a vertical axis) of the pattern of the resist film 18, 19 obtained after the developing step. It is found from FIG. 13 that the line width of the pattern of the resist film 18, 19 is the standard line width that is constant regardless of whether the actual transition time is longer or shorter than the standard transition time T2. This may be caused since the process time for the developing is adjusted to match the process time necessary for the development according to the varying transition time and the resist film 18, 19 is always developed appropriately.

Furthermore, as illustrated in FIG. 10, the extraction process device 27 includes the storing section 27A storing a data table at least representing relations between the transition time from the coating finish time to the development starting time and the transfer speed (the process time necessary for the development) of the mother glass substrate 10MG transferred by the substrate transfer section 22B included in the developing device 22. Therefore, the extraction process device 27 reads the data table stored in the storing section 27A based on the extracted transition time and extracts the transfer speed of the mother glass substrate 10MG. Accordingly, it is not necessary to store the data table in the storing device 26. Therefore, the existing storing device 26 storing the coating finish time is only connected to the extraction process device 27 through the information transmit line 28. Accordingly, existing process management system MS is not necessary to be greatly changed and this is preferable to reduce a cost.

Next, a specific example of the data table stored in the storing section 27A will be described with reference to FIG. 14. FIG. 14 illustrates the data table. In the data table illustrated in FIG. 14, the transition time (a unit is “h”(hours)) from the coating finish time to the development starting time and the transfer speed (no unit) of the mother glass substrate 10MG transferred by the substrate transfer section 22B included in the developing device 22 are described. In the present embodiment, two kinds of liquid crystal panels 10 including two models α and β are to be produced and a type of the CF substrate 10A included in the liquid crystal panel 10 is different between the models α and β. The type of the CF substrate 10A is defined by material, film thickness, and an area of the color filter 14 and the light blocking section 15 and they may be different in each model α, β of the liquid crystal panel 10. The “area” is varied depending on the definition (resolution) or a screen size of the liquid crystal panel 10 and is related to the exposure area or the non-exposure area of the resist film 18, 19 in the exposing step included in the CF substrate producing process. All of the material, the film thickness, and the area of the color filter 14 and the light blocking section 15 may differ between the liquid crystal panels 10 of two models α and β but only some of them may differ. FIG. 14 illustrates the transfer speed of the mother glass substrate 10MG (represented by “A, B, I, J” in FIG. 14) for each model α, β when the light blocking resist film 18 of the light blocking section 15 (represented by “light blocking section” in FIG. 14) is developed. FIG. 14 illustrates the transfer speed of the mother glass substrate 10MG (represented by “C, D, E, F, G, H, K, L, M, N, O, P” in FIG. 14) for each model α, β when the color resist film 19 for each of the red color filter 14R (represented by “CF(R)” in FIG. 14), the green color filter 14G (represented by “CF(G)” in FIG. 14), and the blue color filter 14B (represented by “CF(B)” in FIG. 14) is developed. The transfer speed of the mother glass substrate 10MG described in FIG. 14 is defined while considering difference in the material, the film thickness, and the area of the color filter 14 and the light blocking section 15 according to each model α, β. In FIG. 14, two patterns of duration times, which are 0 to 12 hours and 12 to 24 hours, are described as the transition time.

A specific process using the data table illustrated in FIG. 14 will be described. In the developing step included in the CF substrate producing process, the extraction process device 27 reads out at least the coating finish time from the storing device 26 through the information transmit line 28 and extracts the transition time that is from the coating finish time to the development starting time. The extraction process device 27 also reads out the model α, β associated with the lot number and information relating the target resist film 18, 19 to be processed from the storing device 26 through the information transmit line 28 and specifies the model α or β and the target resist film 18 or 19. Then, the extraction process device 27 extracts the transfer speed of the mother glass substrate 10MG based on the transition time, the model α or β, and the target resist film 18 or 19 and with reference to the data table of FIG. 14. For example, if the transition time is ten hours, the model is α, and the target to be processed is the color resist film 19 for the red color filter 14R, the transfer speed of the mother glass substrate 10MG is “C”. If the transition time is fourteen hours, the model is β, and the target to be processed is the light blocking resist film 18 for the light blocking section 15, the transfer speed of the mother glass substrate 10MG is “J”. After the transfer speed of the mother glass substrate 10MG is extracted, the development control device 25 obtains information relating the transfer speed of the mother glass substrate 10MG from the extraction process device 27 through the information transmit line 28 and controls the substrate transfer section 22B of the developing device 22 based on the information relating the transfer speed. Accordingly, the mother glass substrate 10MG is transferred at the transfer speed that is obtained with considering the transition time from the coating finish time to the development starting time, and the material, the film thickness, and the area of the resist film 18, 19. Therefore, the appropriate process time for the development is obtained.

As described before, the method of producing the CF substrate (a substrate including a resist film) 10A of the present embodiment includes the coating step of coating the resist film 18, 19 on the mother glass substrate (substrate) 10MG, the exposing step of selectively exposing the resist film 18, 19 formed in the coating step, and the developing step of developing the resist film 18, 19 that is selectively exposed in the exposing step. In the developing step, the process time for development is controlled based on the transition time for shifting to the development step after the coating step.

First, in the coating step, the resist film 18, 19 is coated on the mother glass substrate 10MG. In the exposing step, the resist film 18, 19 formed on the mother glass substrate 10MG in the coating step is selectively exposed. Accordingly, the exposed section and the non-exposed section are created in the resist film 18, 19. In the developing step, the resist 18, 19 that is selectively exposed in the exposing step is developed. Accordingly, one of the exposed section and the non-exposed section of the resist film 18, 19 is removed and another remains so as to form a predetermined pattern. The transition time for shifting to the developing step after the coating step may be varied due to various reasons in the producing process. The process time necessary for the development in the developing step tends to be longer as the transition time becomes longer. In this respect, in the developing step, the process time for the development is adjusted by the transition time taken for shifting to the developing step after the coating step. Therefore, the development is appropriately performed even if the transition time is varied. Accordingly, a pattern is appropriately formed on the resist film 18, 19.

In the developing step, the process time is adjusted while considering the material of the resist film 18, 19 in addition to the transition time. The process time necessary for the development in the developing step may be varied depending on the material of the resist film 18, 19 other than the above described transition time. In this respect, in the developing step, the process time is adjusted by considering the material of the resist film 18, 19 in addition to the transition time. Therefore, the development appropriate for the material used for the resist film 18, 19 performed. Thus, the resist film 18, 19 is appropriately processed with patterning.

In the developing step, the process time is adjusted while considering the film thickness of the resist film 18, 19 in addition to the transition time. The process time necessary for the development in the developing step may be varied depending on the film thickness of the resist film 18, 19 other than the above described transition time. In this respect, in the developing step, the process time is adjusted by considering the film thickness of the resist film 18, 19 in addition to the transition time. Therefore, the development appropriate for the film thickness of the resist film 18, 19 to be used is performed. Thus, the resist film 18, 19 is appropriately processed with patterning.

In the developing step, the process time is adjusted while considering the exposure area or the non-exposure area of the resist film 18, 19 in addition to the transition time. The exposure area or the non-exposure area of the resist film 18, 19 in the exposing step is related to the area of the pattern formed with the resist film 18, 19 remaining on the mother glass substrate 10MG after the developing step. The process time necessary for the development in the developing step may be varied depending on the area the pattern formed with the resist film 18, 19 other than the above described transition time. In this respect, the developing step, the process time is adjusted by considering the exposure area or the non-exposure area of the resist film 18, 19 in addition to the transition time. Therefore, the development appropriate for the area of the pattern formed with the resist film 18, 19 remaining on the mother glass substrate 10MG performed. Thus, the resist film 18, 19 is appropriately processed with patterning.

In the developing step, the developer is supplied onto the mother glass substrate 10MG while the mother glass substrate 10MG being transferred and the transfer speed of the mother glass substrate 10MG is controlled to adjust the process time. Accordingly, the developing step, the mother glass substrate 10MG that is transferred at predetermined transfer speed is supplied with the developer such that the development is performed efficiently. The process time for the development becomes longer as the transfer speed of the mother glass substrate 10MG is slower, and the process time for the development becomes shorter as the transfer speed of the mother glass substrate 10MG is faster. Therefore, the process time for the development can be appropriately adjusted by controlling the transfer speed of the mother glass substrate 10MG.

In the coating step, the color resist film 19 or the light blocking resist film 18 is disposed as the resist film 18, 19. Accordingly, the color resist film 19 or the light blocking resist film 18 that is the resist film 18, 19 is appropriately processed with patterning.

The process management system MS for producing the CF substrate 10A according to the present embodiment includes the coating device 20 that forms the resist film 18, 19 on the mother glass substrate 10MG, the exposing device 21 that selectively exposes the resist film 18, 19, the developing device 22 that develops the resist film 18, 19, the storing device 26 that stores at least the coating finish time when the coating of the resist film 18, 19 by the coating device 20 is finished, the extraction process device 27, the development control device 25, and the information transmit lines 28 that connect at least the coating device 20, the extraction process device 27, and the development control device 25 to the storing device 26 so as to transmit information therebetween. The extraction process device 27 reads out the coating finish time stored in the storing device 26 and extracts the transition time taken for shifting to the development by the developing device 22 after the coating of the resist film 18, 19 by the coating device 20, and extracts the process time for the development by the developing device 22 based on the extracted transition time. The development control device 25 controls the development by the developing device 22 based on the process time extracted by the extraction process device 27.

First, the resist film 18, 19 is formed on the mother glass substrate 10MG by the coating device 20. If the resist film 18, 19 formed on the mother glass substrate 10MG is selectively exposed, the exposed section and the non-exposed section are created in the resist film 18, 19. If the resist film 18, 19 that is selectively exposed is developed, one of the exposed section and the non-exposed section of the resist film 18, 19 is removed and another one remains so as to form a predetermined pattern. The development control device 25 controls the developing device 22 to perform development. At least the coating finish time when the coating of the resist film 18, 19 by the coating device 20 is finished is transmit to the storing device 26 through the information transmit line 28 and stored therein.

The transition time necessary for shifting to the development by the developing device after the coating with the resist film 18, 19 performed by the coating device 20 may be varied due to the various reasons in the producing process. The process time necessary for the development by the developing device 22 tends to be longer as the transition time becomes longer. The extraction process device 27 reads out the coating finish time stored in the storing device 26 through the information transmit line 28 and extracts the transition time for shifting to the development by the developing device 22 after the coating of the resist film 18, 19 by the coating device 20 based on the read coating finish time. Then, the extraction process device 27 extracts the process time for the development by the developing device 22 based on the extracted transition time. The development control device 25 reads out the process time extracted by the extraction process device 27 through the information transmit line 28 and controls the development by the developing device 22 based on the read process time. Therefore, the development is appropriately performed even if the transition time is varied. Accordingly, a pattern is appropriately formed on the resist film 18, 19.

The extraction process device 27 includes the storing section (a data table storing section) 27A that at least stores the data table representing the relations between the transition time and the process time. The extraction process device 27 reads out the coating finish time from the storing device 26 and extracts the process time from the data table stored in the storing section 27A based on the transition time extracted by reading the coating finish time from the storing device 26. Accordingly, the extraction process device 27 extracts the transition time based on the coating finish time read from the storing device 26 through the information transmit line 28 while extracting the process time by reading the data table from the storing section 27A that is included in the extraction process device 27 itself. Therefore, the storing device 26 is not necessary to store the data table and the extraction process device 27 is only connected to the existing storing device 26 through the information transmit line 28. Accordingly, the existing process management system MS is not necessary to be greatly changed and this is preferable to reduce a cost.

The development control device 25 is connected to the extraction process device 27 with the information transmit line 28 so as to transmit information therebetween. If the development control device 25 is connected directly to the extraction process device 27 with the information transmit line 28, the storing device 26 is required to be changed to store the process time extracted by the extraction process device 27. Compared to such a configuration, the development control device 25 can directly read out the process time extracted by the extraction process device 27 through the information transmit line 28. Therefore, the storing device 26 is not necessary to be changed.

The developing device 22 at least includes the substrate transfer section 22B that transfers the mother glass substrate 10MG, and the developer supply section 22C that supplies the developer to the mother glass substrate 10MG that is transferred by the substrate transfer section. The development control device 25 controls the transfer speed of the mother glass substrate 10MG by the substrate transfer section 22B to adjust the process time. Accordingly, the developing device 22 effectively performs development by transferring the mother glass substrate 10MG at predetermined transfer speed with the substrate transfer section 22B and supplying the developer onto the mother glass substrate 10MG with the developer supply section 22C. The process time for the development becomes longer as the transfer speed of the mother glass substrate 10MG by the substrate transfer section 22B is slower, and the process time for the development becomes shorter as the transfer speed of the mother glass substrate 10MG by the substrate transfer section 22B is faster. Therefore, the development control device 25 controls the transfer speed of the mother glass substrate 10MG by the substrate transfer section 22B to appropriately adjust the process time for the development.

### Other Embodiments

The present technology is not limited to the embodiments described in the above descriptions and drawings. The following embodiments may be included in the technical scope.

(1) In the above embodiment, in the data table, the number of models of the liquid crystal panels to be produced is two. However, the number of models of the liquid crystal panels to be produced may be three or more.

(2) In the above embodiment, the transition time for shifting to the developing step after the coating process has two patterns of duration times, which are 0 to 12 hours and 12 to 24 hours, in the data table. The patterns of the duration times of the transition time may be three or more. Specifically, three patterns of “0-8 hours”, “8-16 hours”, and “16-24 hours”, four patterns of “0-6 hours”, “6-12 hours”, “12-18 hours”, and “18-24 hours”, six patterns of “0-4 hours”, “4-8 hours”, “8-12 hours”, “12-16 hours”, “16-20 hours”, and “20 to 24 hours”, or eight patterns of “0-3 hours”, “3-6 hours”, “6-9 hours”, “9-12 hours”, “12-15 hours”, “15-18 hours”, 18-21 hours”, and “21-24 hours”. Other than the above patterns, the specific patterns of duration times of the transition time may be altered as appropriate. The greatest value of the transition time may be 24 hours or longer or may be 24 hours or shorter.

(3) In the above embodiment, the transfer speed is included in the data table; however, the process time for the development may be included in the data table. In such a configuration, the development control device may compute the transfer speed of the mother glass substrate based on the process time for the development that is read from the storing section of the extraction process device and control the developing device to transfer the mother glass substrate based on the transfer speed.

(4) In the above embodiment, the storing section included in the extraction process device stores the data table. However, the data table may be stored in the storing device.

(5) In the above embodiment, the method of producing the CF substrate including the resist film made of photosensitive material including the coating step, the exposing step, and the developing step is described. However, the CF substrate may include a film made of non-photosensitive material (metal material, transparent electrode material, non-photosensitive resin material). In performing the coating step, the exposing step, and the developing step for a resist film that is stacked on the film to be etched in etching the film, the process time for the development may be adjusted based on the transition time for shifting to the developing step after the coating step.

(6) In the above embodiment, the method of producing the CF substrate and the process management system for producing the CF substrate are described. The method of producing an array substrate and the process management system for producing an array substrate are also included in the technical scope. For example, various kinds of films included in the array substrate may include a resist film. In performing the coating step, the exposing step, and the developing step for the resist film, the process time for the development may be adjusted based on the transition time until the process is shifted to the developing step after the coating step. The array substrate may include a film made of non-photosensitive material (metal material, transparent electrode material, non-photosensitive resin material) and in performing the coating step, the exposing step, and the developing step for a resist film that is stacked on the film to be etched in etching the film, the process time for the development may be adjusted based on the transition time for shifting to the developing step after the coating step.

(7) In the above embodiment, the developing device is configured to perform development such that the developer is supplied by the developer supply section while the mother glass substrate being transferred by the substrate transfer section. Other than that, the developer may be supplied by the developer supply section to the mother glass substrate that is not moving in the developing device to perform the development. In such a configuration, the time of supplying the developer by the developer supply section is the process time for the development.

(8) In the above embodiment, the material of the resist film is negative-type photosensitive material; however, positive-type photosensitive material may be used as the material of the resist film. In performing the developing step with such a configuration, the exposed section of the resist film is removed from the mother glass substrate and the non-exposed section remains on the mother glass substrate.

(9) In the above embodiment, the development control device is connected to the extraction process device directly with the information transmit line. However, the development control device and the extraction process device may not be directly connected to each other. In such a configuration, the process time extracted by the extraction process device may be stored in the storing device and the development control device may read the process time stored in the storing device and control the developing device to perform the development for the process time.

(10) In the above embodiment, the number of colors of the color filters is three; however, the specific number of colors of the color filters may be altered as appropriate.

(11) Other than the above embodiment, the specific structure of the CF substrate may be altered as appropriate. For example, an overcoat film may be disposed on the color filter.

(12) In the above embodiment, the method of producing the CF substrate of the liquid crystal panel that is operated in the VA mode is described. Other than that, the method of producing the CF substrate of the liquid crystal panel that is operated in other operation modes such as the in-plane switching (IPS) mode or the fringe field switching (FFS) mode may be included in the technical scope.

(13) In the above embodiment, the transmission type liquid crystal panel is described; however, a reflection type liquid crystal panel or a transflective type liquid crystal panel may be used.

(14) In the above embodiment, the method of producing the CF substrate included in the liquid crystal panel is described. However, other types of display panels (e.g., organic EL panels, plasma display panels (PDP), electrophoretic display panels (EPD), and micro electro mechanical system (MEMS) display panels) may be used and the method of producing a substrate including a resist film for such a panel is also included in the scope.

1. A method of producing a substrate including a resist film, the method comprising:
a coating step of coating a resist film on a substrate;
an exposing step of exposing selectively the resist film formed in the coating step; and
a developing step of developing the resist film that is selectively exposed in the exposing step and adjusting process time for development based on transition time for shifting to the developing step after the coating step.

2. The method of producing a substrate including a resist film according to claim 1, wherein in the developing step, the process time is adjusted while considering material of the resist film in addition to the transition time.

3. The method of producing a substrate including a resist film according to claim 1, wherein in the developing step, the process time is adjusted while considering film thickness of the resist film in addition to the transition time.

4. The method of producing a substrate including a resist film according to claim 1, wherein in the developing step, the process time is adjusted while considering an exposed area or a non-exposed area of the resist film in addition to the transition time.

5. The method of producing a substrate including a resist film according to claim 1, wherein in the developing step, developer is supplied onto the substrate while the substrate being transferred, and the process time is adjusted by controlling transfer speed of the substrate.

6. The method of producing a substrate including a resist film according to claim 1, wherein in the coating step, a color resist film or a light blocking resist film is formed as the resist film.

7. A process management system for producing a substrate including a resist film, the process management system comprising:
a coating device configured to coating a resist film on a substrate;
an exposing device configured to selectively expose the resist film;
a developing device configured to develop the resist film;
a storing device configured to store at least coating finish time that is time when the coating device finishes coating of the resist film;
an extraction process device configured to read out the coating finish time stored in the storing device to extract transition time for shifting to development by the developing device after the coating of the resist film by the coating device, and configured to extract process time for development by the developing device based on the extracted transition time;
a development control device configured to control development by the developing device based on the process time extracted by the extraction process device; and
information transmit lines connecting at least the coating device, the extraction process device, and the development control device to the storing device so as to transmit information therebetween.

8. The process management system for producing a substrate including a resist film according to claim 7, wherein the extraction process device includes a data table storing section storing a data table having relations between at least the transition time and the process time, and the extraction process device is configured to extract the process time from the data table stored in the data table storing section based on the transition time that is extracted by reading out the coating finish time from the storing device.

9. The process management system for producing a substrate including a resist film according to claim 7, wherein the development control device is connected to the extraction process device with the information transmit line so as to transmit information therebetween.

10. The process management system for producing a substrate including a resist film according to claim 7, wherein
the developing device at least includes a substrate transfer section transferring the substrate, and a developer supply the section supplying developer to the substrate transferred by the substrate transfer section, and
the development control device is configured to control transfer speed of the substrate by the substrate transfer section to adjust the process time.
